(19) United States
(12) Patent Application Publication
(10) Pub. No.: US 2026/0271313 A1
(43) Pub. Date: Sep. 10, 2026

(54) CAPACITANCE DESIGN AND METHOD OF FORMING THE SAME

(71) Applicant: United Microelectronics Corp., Hsinchu (TW)

(72) Inventors: Yao-Hsien Chung, Tainan City (TW); Fu-Yu Tsai, Tainan City (TW); Bin-Siang Tsai, Changhua County (TW)

(73) Assignee: United Microelectronics Corp., Hsinchu (TW)

(21) Appl. No.: 19/090,417

(22) Filed: Mar. 26, 2025

(30) Foreign Application Priority Data
Mar. 10, 2025 (TW) 114108667

(51) Int. Cl. H10D 1/68; H10D 1/00

(52) U.S. Cl. CPC H10D 1/714; H10D 1/043; H10D 1/716

(57) ABSTRACT

A capacitance design and a method of forming the same are provided. The capacitance design includes: a substrate, including a silicon nitride layer, a first silicon oxide layer, a silicon layer, and a second silicon oxide layer from top to bottom along a vertical direction; an opening in the silicon nitride layer, the first silicon oxide layer, the silicon layer, and the second silicon oxide layer; and an insulator-shape capacitor conformally on a surface of the opening. The opening includes a trench in the silicon nitride layer, the first silicon oxide layer, the silicon layer, and the second silicon oxide layer along the vertical direction; and a first toroidal cavity and a second toroidal cavity respectively in the first silicon oxide layer and the second silicon oxide layer along a horizontal direction perpendicular to the vertical direction from the trench.

### CROSS-REFERENCE TO RELATED APPLICATION

This application claims the priority benefit of Taiwan application serial no. 114108667, filed on Mar. 10, 2025. The entirety of the above-mentioned patent application is hereby incorporated by reference herein and made a part of this specification.

### BACKGROUND

### Technical Field

The disclosure relates to a capacitance design, and more particularly, to a capacitance design and a method of forming the same.

### Description of Related Art

As semiconductor manufacturing processes pursue a higher degree of integration, capacitance elements are also expected to have higher capacitance values in the same layout area. Therefore, various manufacturing process technologies for the capacitance elements such as deep trench capacitors (DTC) have been developed.

However, there is still room for further improvement in the capacitance values of the capacitance elements.

### SUMMARY

Based on the above issues, the disclosure provides a capacitance design and a method of forming the same to increase a capacitance value.

An embodiment of the disclosure provides a capacitance design, including a substrate including a silicon nitride layer, a first silicon oxide layer, a silicon layer, and a second silicon oxide layer from top to bottom along a vertical direction; an opening located in the silicon nitride layer, the first silicon oxide layer, the silicon layer, and the second silicon oxide layer, in which the opening includes a trench located in the silicon nitride layer, the second silicon oxide layer, the silicon layer, and the first silicon oxide layer along the vertical direction, and a first toroidal cavity and a second toroidal cavity respectively located in the first silicon oxide layer and the second silicon oxide layer along a horizontal direction perpendicular to the vertical direction from the trench; and an insulator-shape capacitor conformally located on a surface of the opening.

In some embodiments, the substrate further includes an etch stop layer located below the second silicon oxide layer.

In some embodiments, a bottom of the opening exposes the etch stop layer.

In some embodiments, the insulator-shape capacitor includes a lower electrode layer conformally located on the surface of the opening; a dielectric layer conformally located on the lower electrode layer; and an upper electrode layer conformally located on the dielectric layer.

In some embodiments, the insulator-shape capacitor includes a metal/insulator/metal stacking structure.

In some embodiments, the insulator-shape capacitor includes a TiN-ZAZ-TiN stacking structure or a TAN/ZAZ/TAN stacking structure.

In some embodiments, the capacitance design further includes the insulator-shape capacitor located on a top surface of the silicon nitride layer; and a lower electrode and an upper electrode located on the insulator-shape capacitor of the silicon nitride layer. The lower electrode is electrically connected to the lower electrode layer, and the upper electrode is electrically connected to the upper electrode layer.

In some embodiments, the capacitance design further includes an additional silicon oxide layer and an additional silicon nitride layer located between the first silicon oxide layer and the silicon layer, in which the opening is further located in the additional silicon oxide layer and the additional silicon nitride layer, and the opening includes the trench further located in the additional silicon nitride layer and the additional silicon oxide layer along the vertical direction; and a third toroidal cavity located in the additional silicon oxide layer in the horizontal direction in the trench.

An embodiment of the disclosure provides a method of forming a capacitance design, includes the following. A substrate is provided, including a silicon nitride layer, a first silicon oxide layer, a silicon layer, and a second silicon oxide layer from top to bottom along a vertical direction. An opening is formed in the silicon nitride layer, the first silicon oxide layer, the silicon layer, and the second silicon oxide layer. Forming the opening includes the following. A trench is formed in the silicon nitride layer, the first silicon oxide layer, the silicon layer, and the second silicon oxide layer along the vertical direction. A portion of the first silicon oxide layer and a portion of the second silicon oxide layer are removed along a horizontal direction perpendicular to the vertical direction from the trench to form a first toroidal cavity and a second toroidal cavity respectively in the first silicon oxide layer and the second silicon oxide layer. An insulator-shape capacitor is conformally formed on a surface of the opening.

In some embodiments, the substrate further includes an etch stop layer located below the second silicon oxide layer.

In some embodiments, a bottom of the opening exposes the etch stop layer.

In some embodiments, forming the first toroidal cavity and the second toroidal cavity includes an isotropic etching process or an anisotropic etching process.

In some embodiments, forming the first toroidal cavity and the second toroidal cavity includes forming at the same time by an isotropic etching process or forming at the same time by an anisotropic etching process.

In some embodiments, forming the insulator-shape capacitor includes the following. A lower electrode layer is conformally formed on the surface of the opening. A dielectric layer is conformally formed on the lower electrode layer. An upper electrode layer is conformally formed on the dielectric layer.

In some embodiments, the insulator-shape capacitor includes a metal/insulator/metal stacking structure.

In some embodiments, the insulator-shape capacitor comprises a TiN-ZAZ-TiN stacking structure or a TAN/ZAZ/TAN stacking structure.

In some embodiments, the method of forming the capacitance design further includes the following. The insulator-shape capacitor is formed on a top surface of the silicon nitride layer. A lower electrode and an upper electrode are formed on the insulator-shape capacitor of the silicon nitride layer. The lower electrode is electrically connected to the lower electrode layer, and the upper electrode is electrically connected to the upper electrode layer.

In some embodiments, the method of forming the capacitance design further includes the following. An additional silicon nitride layer and an additional silicon oxide layer are formed between the first silicon oxide layer and the silicon layer. The opening is further formed in the additional silicon nitride layer and the additional silicon oxide layer. Forming the opening includes the following. A trench is formed in the additional silicon nitride layer and the additional silicon oxide layer along the vertical direction. A portion of the additional silicon oxide layer is removed along the horizontal direction from the trench to form a third toroidal cavity in the additional silicon oxide layer.

In some embodiments, forming the first toroidal cavity, the second toroidal cavity, and the third toroidal cavity includes an isotropic etching process or an anisotropic etching process.

In some embodiments, forming the first toroidal cavity, the second toroidal cavity, and the third toroidal cavity includes forming at the same time by an isotropic etching process or forming at the same time by an anisotropic etching process.

Based on the above, the disclosure provides the capacitance design and the method of forming the same. By the characteristics of different material layers inside the trench having the relatively large etching selectivity, the lateral expansion is further performed in the special material inside the trench by etching to form the toroidal cavities, so that the capacitor formed subsequently has the shape like the insulator, so as to increase the surface area of the capacitor under the same layout area or the same aspect ratio of the trench, thereby increasing the capacitance value of the capacitor while maintaining the degree of integration of the semiconductor element.

In order for the aforementioned features and advantages of the disclosure to be more comprehensible, embodiments accompanied with drawings are described in detail below.

### BRIEF DESCRIPTION OF THE DRAWINGS

FIGS. 1A to 1E are schematic cross-sectional views of a method of forming a capacitance design according to Embodiment 1 of the disclosure.

FIG. 2 is a schematic cross-sectional view of a capacitance design according to Embodiment 2 of the disclosure.

FIGS. 3A to 3B are schematic cross-sectional views of a method of forming a multi-wafer stacking structure according to Embodiment 3 of the disclosure.

### DETAILED DESCRIPTION OF DISCLOSED EMBODIMENTS

The embodiments are described in detail below with reference to the accompanying drawings, but the provided embodiments are not intended to limit the scope of the disclosure. In addition, the drawings are drawn only for the purpose of description, and are not drawn according to original sizes. For ease of understanding, the same elements in the following description will be denoted by the same reference numerals and will not be described in detail in the following paragraphs.

Terms such as “include”, “comprise”, and “have” used herein are all inclusive terms, which also refers to “including but not limited to”.

In addition, directional terms, such as “on”, “under”, “top”, “bottom” mentioned herein are only used to refer to the direction of the drawings, and are not used to limit the disclosure. Thus, it will be understood that “on” is used interchangeably with “under” and “top” is used interchangeably with “bottom”. In addition, when an element such as a layer or film is placed “on” another element, the element may be directly on the other element, or there may be an intervening member therebetween. On the other hand, when an element is referred to as being “directly on” another element, there is no intervening element therebetween.

The term “about”, “approximately”, or “substantially” used herein includes the value and an average value within an acceptable deviation range of specific values determined by a person of ordinary skill in the art, taking into account discussed measurements and a specific number of measurement-related errors (i.e., limitations of a measuring system). For example, the term “about” may mean being within one or more standard deviations of the value, or within ±30%, ±20%, ±10%, and ±5%. Moreover, the term “about”, “approximately”, or “substantially” used herein may mean selecting a more acceptable deviation range or standard deviations according to optical properties, etching properties, or other properties, without applying a single standard deviation to all properties.

The terms used herein are used to merely describe exemplary embodiments and are not used to limit the disclosure. In this case, unless indicated in the context specifically, otherwise the singular forms include the plural forms.

Various forming steps described below include a deposition process, a removal process, a patterning process, etc.

The deposition process refers to a process of forming one material on another material, which may include technologies such as spin coating, sputtering, chemical vapor deposition (CVD), physical vapor deposition (PVD), plasma enhanced chemical vapor deposition (PE-CVD), atomic layer deposition (ALD), molecular beam deposition (MBD), pulsed laser deposition (PLD), liquid source misted chemical deposition (LSMCD), but the disclosure is not limited thereto.

The removal process may include wet etching, dry etching, chemical mechanical planarization (CMP), etc., but the disclosure is not limited thereto.

The patterning process may include steps such as coating a photoresist according to a pattern to be formed, then causing the photoresist to react by exposure, performing exposure developing to pattern the photoresist, transferring a photoresist shape to the material by etching, removing the material to be removed and the photoresist, and finally performing cleaning, but the disclosure is not limited thereto.

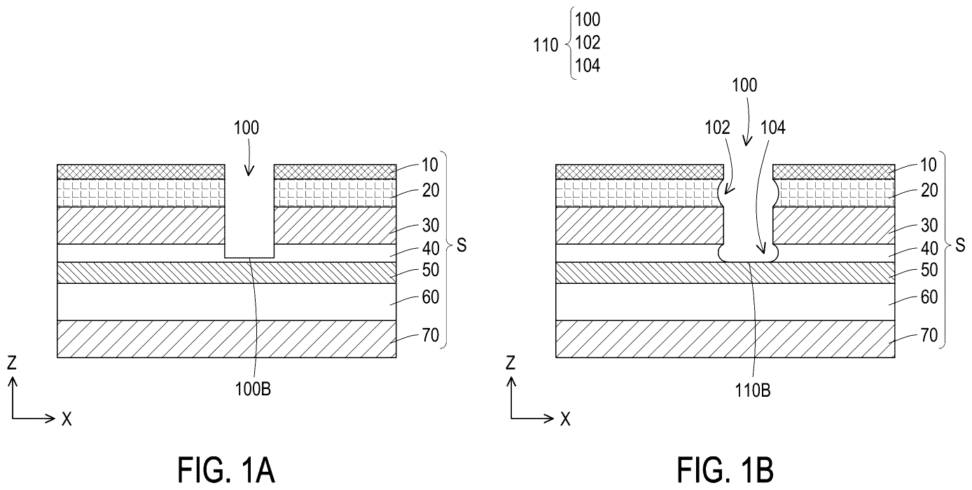

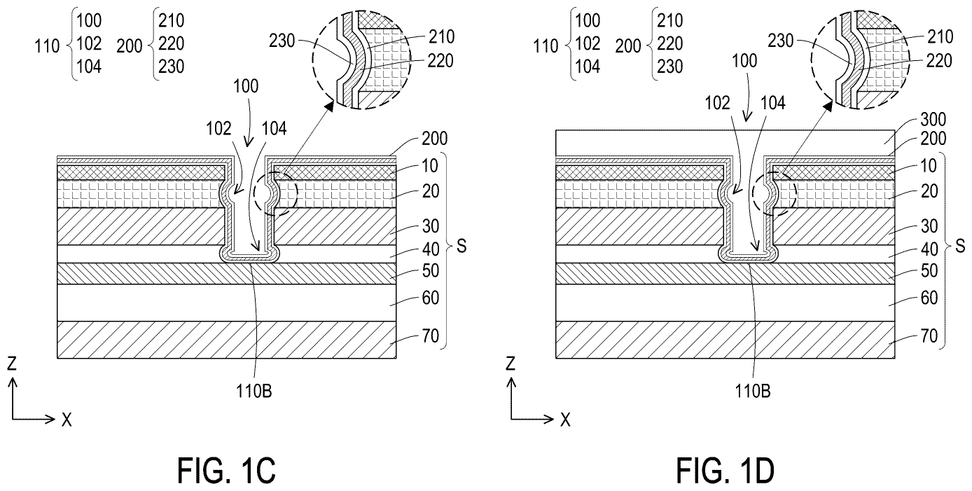

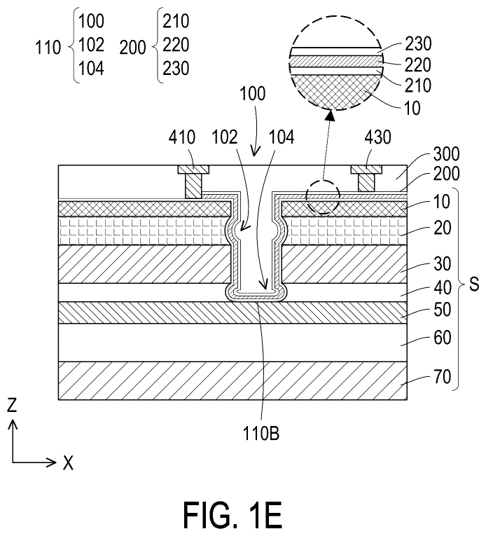

Regarding a capacitance design, a multi-wafer stacking structure, and a method of forming the same in the disclosure, reference may be made to the following Embodiments 1 to 3 with reference to FIGS. 1A to 3B for understanding.

### Embodiment 1

FIGS. 1A to 1E are schematic cross-sectional views of a method of forming a capacitance design according to Embodiment 1 of the disclosure.

First, referring to FIG. 1A, a substrate S is provided, which includes a silicon nitride layer 10, a first silicon oxide layer 20, a silicon layer 30, and a second silicon oxide layer 40 from top to bottom along a vertical direction Z.

In some embodiments, the silicon nitride layer 10 may include materials such as silicon oxynitride, but the disclosure is not limited thereto.

In some embodiments, the first silicon oxide layer 20 may include materials such as tetraethoxysilane (TEOS), but the disclosure is not limited thereto.

In some embodiments, the silicon layer 30 may include a silicon material, but the disclosure is not limited thereto.

In some embodiments, the second silicon oxide layer 40 may further include materials such as a silicon oxide filler for forming STI, but the disclosure is not limited thereto.

In some embodiments, the substrate S may further include an etch stop layer 50 below the second silicon oxide layer 40, as shown in FIG. 1A.

In some embodiments, the substrate S may further include the etch stop layer 50, a dielectric layer 60, and a metal layer 70 below the second silicon oxide layer 40. The etch stop layer 50 may be located on the interlayer dielectric layer 60, as shown in FIG. 1A, or the etch stop layer 50 may be located in the interlayer dielectric layer 60 (not shown).

In some embodiments, the etch stop layer 50 may include materials such as silicon nitride, but the disclosure is not limited thereto.

In some embodiments, the metal layer 70 may include various conductive materials, such as copper (Cu), tungsten (W), aluminum (Al), titanium (Ti), nickel (Ni), platinum (Pt), ruthenium (Ru), cobalt (Co), or alloys thereof or other suitable conductive materials developed in the future, but the disclosure is not limited thereto.

Then, continuing to refer to FIG. 1A, along the vertical direction Z, a trench 100 is formed in the silicon nitride layer 10, the first silicon oxide layer 20, the silicon layer 30, and the second silicon oxide layer 40.

In some embodiments, the trench 100 may be formed by using various patterning processes, such as a photolithography process and an etching process.

In some embodiments, a bottom 100B of the formed trench 100 may expose the second silicon oxide layer 40, as shown in FIG. 1A, or the bottom 100B of the formed trench 100 may expose the etch stop layer 50 (not shown).

Next, referring to FIG. 1B, after the trench 100 is formed, a portion of the first silicon oxide layer 20 and a portion of the second silicon oxide layer 40 are removed along a horizontal direction X perpendicular to the vertical direction Z from the trench 100 to form a first toroidal cavity 102 and a second toroidal cavity 104 respectively in the first silicon oxide layer 20 and the second silicon oxide layer 20, so that an opening 110 includes the trench 100, the first toroidal cavity 102, and the second toroidal cavity 104, and the opening 110 is formed in the silicon nitride layer 10, the first silicon oxide layer 20, the silicon layer 30, and the second silicon oxide layer 40.

In some embodiments, a portion of the first silicon oxide layer 20 and a portion of the second silicon oxide layer 40 may be removed along the horizontal direction X perpendicular to the vertical direction Z from the trench 100 by using an isotropic etching process or an anisotropic etching process, so as to form the first toroidal cavity 102 and the second toroidal cavity 104 respectively.

In some embodiments, the first toroidal cavity 102 and the second toroidal cavity 104 may be formed at the same time by using the isotropic etching process or the anisotropic etching process.

In the silicon nitride layer 10, the first silicon oxide layer 20, the silicon layer 30, and the second silicon oxide layer 40, the first silicon oxide layer 20 and the second silicon oxide layer 40 have an etching selectivity difference of about 100 to 1000:1 relative to the silicon nitride layer 10 and the silicon layer 30. That is, after the etching process is performed on the trench 100 using a suitable etchant and etching method, the first silicon oxide layer 20 and the second silicon oxide layer 40 in the trench 100 are removed to a certain extent, while the silicon nitride layer 10 and the silicon layer 30 are retained, so as to form the first toroidal cavity 102 and the second toroidal cavity 104 respectively in the first silicon oxide layer 20 and the second silicon oxide layer 40 along the horizontal direction X perpendicular to the vertical direction Z.

In addition, as shown in FIGS. 1A and 1B, the bottom 100B of the trench 100 may also be affected by the etching of the second toroidal cavity 104, so that a portion of the second silicon oxide layer 40 is further removed downward, and finally a bottom 110B of the formed opening 110B moves toward the etch stop layer 50 more than the bottom 100B of the trench 100, and even exposes the etch stop layer 50, as shown in FIG. 1B.

Next, referring to FIG. 1C, an insulator-shape capacitor 200 is conformally formed on a surface of the opening 110 including the first toroidal cavity 102 and the second toroidal cavity 104.

In some embodiments, before the insulator-shape capacitor 200 is conformally formed on the surface of the opening 110 including the first toroidal cavity 102 and the second toroidal cavity 104, a liner (not shown) may be conformally formed on the surface of the opening 110 including the first toroidal cavity 102 and the second toroidal cavity 104. The liner may include an oxide layer, but the disclosure is not limited thereto.

The so-called insulator is an insulator used in overhead power transmission lines for electrical insulation and mechanical fixation, which has a special shape in which shed-shaped insulators are repeatedly arranged in the same direction on a columnar insulator. The insulator-shape capacitor 200 in the disclosure conformally formed along the surface of the opening 110 including the trench 100, the first toroidal cavity 102 and the second toroidal cavity 104 has a shape similar to that of the insulator, and is therefore named as such.

In some embodiments, the insulator-shape capacitor 200 may include a metal/insulator/metal (MIM) stacking structure, such as a TiN-ZAZ-TiN stacking structure or a TAN/ZAZ/TAN stacking structure, but the disclosure is not limited thereto. The insulator-shape capacitor 200 may also include a general capacitance structure, but the disclosure is not limited thereto.

In some embodiments, the insulator-shape capacitor 200 may include a lower electrode layer 210 conformally formed on the surface of the opening 110, a dielectric layer 220 conformally formed on the lower electrode layer 210, and a lower electrode layer 230 conformally formed on the dielectric layer 220, as shown in FIG. 1C.

In some embodiments, as shown in FIG. 1C, the formed insulator-shape capacitor 200 may be further formed on a top surface of the silicon nitride layer 10.

Then, as shown in FIG. 1D, an insulating layer 300 is deposited on the insulator-shape capacitor 200 to fill the opening 110, and is located above the silicon nitride layer 10.

Next, as shown in FIG. 1E, a lower electrode 410 and an upper electrode 430 are formed on the insulator-shape capacitor 200 of the silicon nitride layer 10. The lower electrode 410 is electrically connected to the lower electrode layer 210, and the upper electrode 430 is electrically connected to the upper electrode layer 230.

That is, in the disclosure, by characteristics of different material layers inside the trench having a relatively large etching selectivity, lateral expansion is further performed in a special material inside the trench by etching to form multiple toroidal cavities, so that the capacitor formed subsequently has a shape like the insulator, so as to increase a surface area of the capacitor under the same layout area or the same aspect ratio of the trench, thereby increasing a capacitance value of the capacitor while maintaining a degree of integration of a semiconductor element.

### Embodiment 2

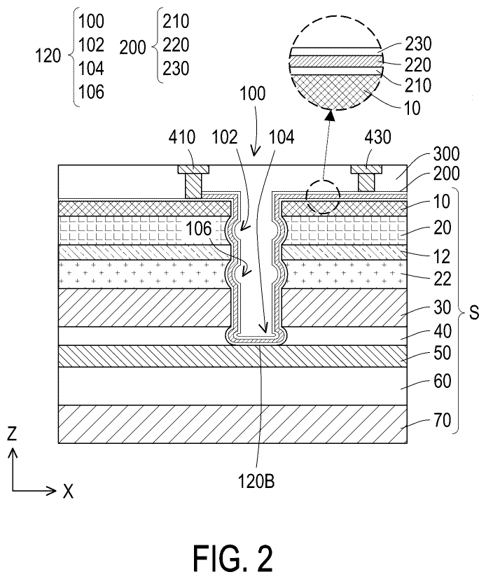

FIG. 2 is a schematic cross-sectional view of a capacitance design according to Embodiment 2 of the disclosure, which is similar to the capacitance design shown in FIG. 1E of Embodiment 1, and a method of forming the capacitance design in Embodiment 2 is similar to the method of forming the capacitance design described in Embodiment 1. Therefore, only differences are described below.

The capacitance design shown in FIG. 2 has an additional silicon nitride layer 12 and an additional silicon oxide layer 22 between the first silicon oxide layer 20 and the silicon layer 30, compared to the capacitance design shown in FIG. 1E. Therefore, the trench 100 of the capacitance design in Embodiment 2 is formed in the silicon nitride layer 10, the first silicon oxide layer 20, the additional silicon nitride layer 12, the additional silicon oxide layer 22, the silicon layer 30, and the second silicon oxide layer 40 along the vertical direction Z.

Continuing to refer to FIG. 2, after the trench 100 is formed, a portion of the first silicon oxide layer 20, a portion of the additional silicon oxide layer 12, and a portion of the second silicon oxide layer 40 are removed along the horizontal direction X perpendicular to the vertical direction Z from the trench 100 to form the first toroidal cavity 102, a third toroidal cavity 106, and the second toroidal cavity 104 respectively in the first silicon oxide layer 20, the additional silicon oxide layer 12, and the second silicon oxide layer 20, so that an opening 120 includes the trench 100, the first toroidal cavity 102, the third toroidal cavity 106, and the second toroidal cavity 104, and the opening 120 is formed in the silicon nitride layer 10, the first silicon oxide layer 20, the additional silicon nitride layer 12, the additional silicon oxide layer 22, the silicon layer 30, and the second silicon oxide layer 40.

In some embodiments, a portion of the first silicon oxide layer 20, a portion of the additional silicon oxide layer 12, and a portion of the second silicon oxide layer 40 may be removed along the horizontal direction X perpendicular to the vertical direction Z from the trench 100 by using the isotropic etching process or the anisotropic etching process, so as to form the first toroidal cavity 102, the third toroidal cavity 106, and the second toroidal cavity 104 respectively.

In some embodiments, the first toroidal cavity 102, the third toroidal cavity 106, and the second toroidal cavity 104 may be formed at the same time by using the isotropic etching process or the anisotropic etching process.

Next, still referring to FIG. 2, the insulator-shape capacitor 200 is conformally formed on a surface of the opening 120 including the first toroidal cavity 102, the third toroidal cavity 106, and the second toroidal cavity 104.

Referring to both the capacitance design in FIG. 1E and the capacitance design in FIG. 2, since the additional silicon nitride layer 12 and the additional silicon oxide layer 22 are provided between the first silicon oxide layer 20 and the silicon layer 30 in Embodiment 2, after steps of forming the opening 120 and the insulator-shape capacitor 200, a greater surface area of the insulator-shape capacitor 200 is obtained than that of the capacitance design in Embodiment 1, so as to obtain the capacitance design in Embodiment 2 with a higher capacitance value.

Therefore, multiple groups of silicon oxide layers and silicon nitride layers may be formed by using a concept of the method of forming the capacitance design in Embodiment 2, so that the opening is formed into a shape including the toroidal cavities, so that the capacitance value of the capacitor formed subsequently may be increased.

### Embodiment 3

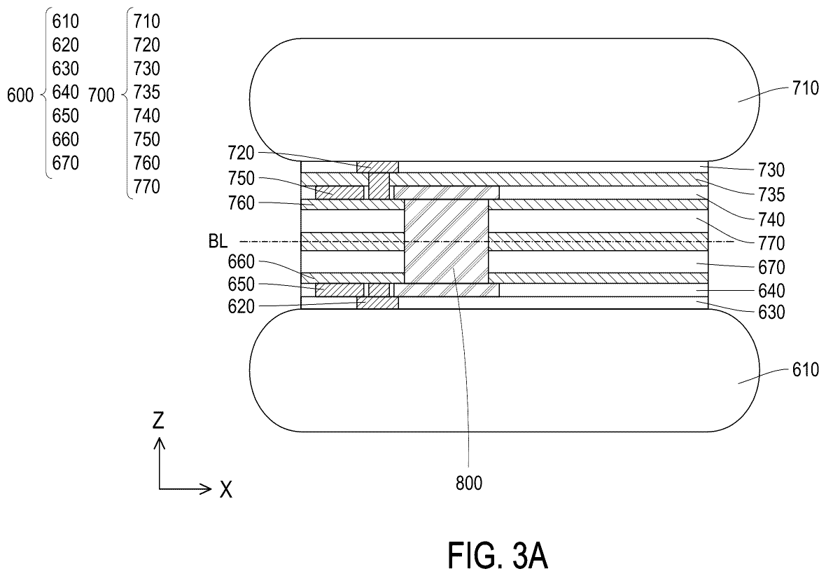

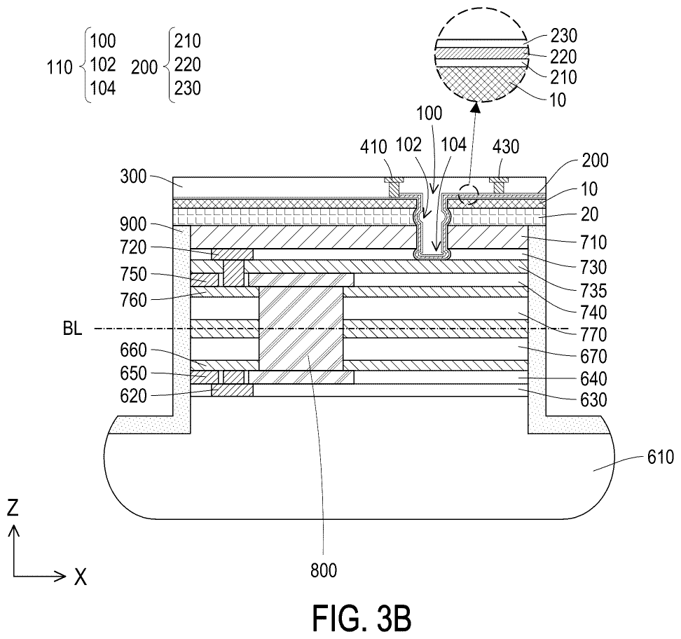

FIGS. 3A to 3B are schematic cross-sectional views of a method of forming a multi-wafer stacking structure according to Embodiment 3 of the disclosure. The multi-wafer stacking structure and the method of forming the same are to embed the capacitance design in Embodiment 1 into the multi-wafer stacking structure, but the concept of the disclosure is not limited thereto. The capacitance design in Embodiment 2 and the similar capacitance design formed by using the concept thereof may also be embedded into the multi-wafer stacking structure. In addition, the multi-wafer stacking structure in FIGS. 3A and 3B is only one of examples for clearly illustrating various multi-wafer stacking structures, and an application of the capacitance design in the disclosure is not limited thereto.

First, referring to FIG. 3A, a bottom wafer structure 600 is provided, including a bottom wafer 610. A top wafer structure 700 is provided, including a top wafer 710 and a top dielectric layer 730. The top wafer structure 700 and the bottom wafer structure 600 are bonded along the vertical direction Z in a manner that the top wafer 710 and the bottom wafer 610 are away from each other.

In some embodiments, the bottom wafer structure 600 further includes a bottom element 620 and a bottom dielectric layer 630 on the bottom wafer 610, further includes a first bottom interlayer dielectric layer 640 and a bottom contact plug 650 on the bottom element 620 and the bottom dielectric layer 630, and further includes a stack of a first bottom metal layer 660 and a second bottom interlayer dielectric layer 670 on the first bottom interlayer dielectric layer 640 and the bottom contact plug 650 in sequence, as shown in FIG. 3A, but the disclosure is not limited thereto.

In some embodiments, the top wafer structure 700 further includes a top element 720 and the top dielectric layer 730 on the top wafer 710, further includes an etch stop layer 735 on the top element 720 and the top dielectric layer 730, further includes a first top interlayer dielectric layer 740 and a bottom contact plug 750 on the etch stop layer 735, and further includes a stack of a first top metal layer 760 and a second top interlayer dielectric layer 770 on the first top interlayer dielectric layer 740 and the bottom contact plug 750 in sequence, as shown in FIG. 3A, but the disclosure is not limited thereto.

In some embodiments, the top wafer structure 700 and the bottom wafer structure 600 are bonded at a bonding interface BL along the vertical direction Z in the manner that the top wafer 710 and the bottom wafer 610 are away from each other, as shown in FIG. 3A, but the disclosure is not limited thereto.

In some embodiments, a through silicon via (TSV) 800 is further included in the bottom wafer structure 600 and the top wafer structure 700, as shown in FIG. 3A, but the disclosure is not limited thereto.

Next, as shown in FIG. 3B, after a chemical mechanical polishing (CMP) grinding process is performed to reduce a thickness of the top wafer 710 to about 3 to 10 microns, a side insulating layer 900 is formed on an exposed upper surface of the bottom wafer 610 and sidewalls of the top wafer structure 700 and the bottom wafer structure 600, as shown in FIG. 3B.

In some embodiments, the side insulating layer 900 may include insulating materials such as TEOS, but the disclosure is not limited thereto.

Next, the first silicon oxide layer 20 is formed on the top wafer 710, and then the silicon nitride layer 10 is formed on the first silicon oxide layer 20.

Next, as steps of forming the capacitance design in Embodiment 1 shown in FIGS. 1A to 1E, the top wafer structure 700, the bottom wafer construction 600, and the second silicon oxide layer 20 and the silicon nitride layer 10 formed thereafter on the top wafer 710 in FIG. 3B are regarded as the substrate S described in Embodiment 1. In particular, the silicon nitride layer 10, the first silicon oxide layer 20, the top wafer 710, and the top dielectric layer 730 in FIG. 3B correspond to the silicon nitride layer 10, the first silicon oxide layer 20, the silicon layer 30, and the second silicon oxide layer 40 in FIGS. 1A to 1E, and the opening 110 is formed in the silicon nitride layer 10, the first silicon oxide layer 20, the top wafer 710, and the top dielectric layer 730. Formation of the opening 110 includes the following. The trench 100 is formed in the silicon nitride layer 10, the first silicon oxide layer 20, the top wafer 710, and the top dielectric layer 730 along the vertical direction Z. A portion of the first silicon oxide layer 20 and a portion of the top dielectric layer 730 are removed along the horizontal direction X perpendicular to the vertical direction Z from the trench 100 to form the first toroidal cavity 102 and the second toroidal cavity 104 respectively in the first silicon oxide layer 20 and the top dielectric layer 730. The insulator-shape capacitor 200 is conformally formed on the surface of the opening 110.

In addition to the silicon nitride layer 10, the first silicon oxide layer 20, the top wafer 710, and the top dielectric layer 730 in FIG. 3B corresponding to the silicon nitride layer 10, the first silicon oxide layer 20, the silicon layer 30, and the second silicon oxide layer 40 in FIGS. 1A to 1E, in some embodiments, the etch stop layer 735, the first top interlayer dielectric layer 740, and the first top metal layer 760 in FIGS. 3A and 3B may also correspond to the etch stop layer 50, the interlayer dielectric layer 60, and the metal layer 70 in FIGS. 1A to 1E.

Then, formation of the multi-wafer stacking structure in Embodiment 3 may be completed by using the method of forming the capacitance design in Embodiment 1 of the disclosure.

Based on the above, the disclosure provides the capacitance design and the method of forming the same. By the characteristics of different material layers inside the trench having the relatively large etching selectivity, the lateral expansion is further performed in the special material inside the trench by etching to form the toroidal cavities, so that the capacitor formed subsequently has the shape like the insulator, so as to increase the surface area of the capacitor under the same layout area or the same aspect ratio of the trench, thereby increasing the capacitance value of the capacitor while maintaining the degree of integration of the semiconductor element.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A capacitance design, comprising:
a substrate comprising a silicon nitride layer, a first silicon oxide layer, a silicon layer, and a second silicon oxide layer from top to bottom along a vertical direction;
an opening located in the silicon nitride layer, the first silicon oxide layer, the silicon layer, and the second silicon oxide layer, wherein the opening comprises:
a trench located in the silicon nitride layer, the second silicon oxide layer, the silicon layer, and the first silicon oxide layer along the vertical direction; and
a first toroidal cavity and a second toroidal cavity respectively located in the first silicon oxide layer and the second silicon oxide layer along a horizontal direction perpendicular to the vertical direction from the trench; and
an insulator-shape capacitor conformally located on a surface of the opening.

2. The capacitance design according to claim 1, wherein the substrate further comprises:
an etch stop layer located below the second silicon oxide layer.

3. The capacitance design according to claim 2, wherein a bottom of the opening exposes the etch stop layer.

4. The capacitance design according to claim 1, wherein the insulator-shape capacitor comprises:
a lower electrode layer conformally located on the surface of the opening;
a dielectric layer conformally located on the lower electrode layer; and
an upper electrode layer conformally located on the dielectric layer.

5. The capacitance design according to claim 1, wherein the insulator-shape capacitor comprises a metal/insulator/metal stacking structure.

6. The capacitance design according to claim 1, wherein the insulator-shape capacitor comprises a TiN-ZAZ-TiN stacking structure or a TAN/ZAZ/TAN stacking structure.

7. The capacitance design according to claim 4, further comprising:
the insulator-shape capacitor located on a top surface of the silicon nitride layer; and
a lower electrode and an upper electrode located on the insulator-shape capacitor of the silicon nitride layer, wherein the lower electrode is electrically connected to the lower electrode layer, and the upper electrode is electrically connected to the upper electrode layer.

8. The capacitance design according to claim 1, further comprising:
an additional silicon oxide layer and an additional silicon nitride layer located between the first silicon oxide layer and the silicon layer;
wherein the opening is further located in the additional silicon oxide layer and the additional silicon nitride layer, and the opening comprises:
the trench further located in the additional silicon nitride layer and the additional silicon oxide layer along the vertical direction; and
a third toroidal cavity located in the additional silicon oxide layer in the horizontal direction in the trench.

9. A method of forming a capacitance design, comprising:
providing a substrate, comprising a silicon nitride layer, a first silicon oxide layer, a silicon layer, and a second silicon oxide layer from top to bottom along a vertical direction;
forming an opening in the silicon nitride layer, the first silicon oxide layer, the silicon layer, and the second silicon oxide layer, wherein forming the opening comprises:
forming a trench in the silicon nitride layer, the first silicon oxide layer, the silicon layer, and the second silicon oxide layer along the vertical direction; and
removing a portion of the first silicon oxide layer and a portion of the second silicon oxide layer along a horizontal direction perpendicular to the vertical direction from the trench to form a first toroidal cavity and a second toroidal cavity respectively in the first silicon oxide layer and the second silicon oxide layer; and
conformally forming an insulator-shape capacitor on a surface of the opening.

10. The method of forming the capacitance design according to claim 9, wherein the substrate further comprises:
an etch stop layer located below the second silicon oxide layer.

11. The method of forming the capacitance design according to claim 10, wherein a bottom of the opening exposes the etch stop layer.

12. The method of forming the capacitance design according to claim 9, wherein forming the first toroidal cavity and the second toroidal cavity comprises an isotropic etching process or an anisotropic etching process.

13. The method of forming the capacitance design according to claim 9, wherein forming the first toroidal cavity and the second toroidal cavity comprises forming at the same time by an isotropic etching process or forming at the same time by an anisotropic etching process.

14. The method of forming the capacitance design according to claim 9, wherein forming the insulator-shape capacitor comprises:
conformally forming a lower electrode layer on the surface of the opening;
conformally forming a dielectric layer on the lower electrode layer; and
conformally forming an upper electrode layer on the dielectric layer.

15. The method of forming the capacitance design according to claim 9, wherein the insulator-shape capacitor comprises a metal/insulator/metal stacking structure.

16. The method of forming the capacitance design according to claim 9, wherein the insulator-shape capacitor comprises a TiN-ZAZ-TiN stacking structure or a TAN/ZAZ/TAN stacking structure.

17. The method of forming the capacitance design according to claim 14, further comprising:
forming the insulator-shape capacitor on a top surface of the silicon nitride layer; and
forming a lower electrode and an upper electrode on the insulator-shape capacitor of the silicon nitride layer, wherein the lower electrode is electrically connected to the lower electrode layer, and the upper electrode is electrically connected to the upper electrode layer.

18. The method of forming the capacitance design according to claim 9, further comprising:
forming an additional silicon nitride layer and an additional silicon oxide layer between the first silicon oxide layer and the silicon layer, and
further forming the opening in the additional silicon nitride layer and the additional silicon oxide layer, wherein forming the opening comprises:
forming a trench in the additional silicon nitride layer and the additional silicon oxide layer along the vertical direction; and
removing a portion of the additional silicon oxide layer along the horizontal direction from the trench to form a third toroidal cavity in the additional silicon oxide layer.

19. The method of forming the capacitance design according to claim 18, wherein forming the first toroidal cavity, the second toroidal cavity, and the third toroidal cavity comprises an isotropic etching process or an anisotropic etching process.

20. The method of forming the capacitance design according to claim 16, wherein forming the first toroidal cavity, the second toroidal cavity, and the third toroidal cavity comprises forming at the same time by an isotropic etching process or forming at the same time by an anisotropic etching process.
